(19) United States
(12) Patent Application Publication
(10) Pub. No.: US 2022/0335991 A1
(43) Pub. Date: Oct. 20, 2022

(54) SEMICONDUCTOR APPARATUS

(71) Applicant: SK hynix Inc., Icheon-si Gyeonggi-do (KR)

(72) Inventor: Hyung Sik WON, Icheon-si Gyeonggi-do (KR)

(73) Assignee: SK hynix Inc., Icheon-si Gyeonggi-do (KR)

(21) Appl. No.: 17/469,559

(22) Filed: Sep. 8, 2021

(30) Foreign Application Priority Data
Apr. 20, 2021 (KR) 10-2021-0051054

(51) Int. Cl. G11C 7/12; G11C 7/08

(52) U.S. Cl. CPC G11C 7/12; G11C 7/08; G11C 2207/065

(57) ABSTRACT

A semiconductor apparatus includes a plurality of bit lines; a plurality of sense amplifiers coupled to the plurality of bit lines, respectively, and configured to sense and amplify corresponding signals; and a sense amplifier driving signal providing circuit configured to drive adjacent sense amplifiers among the plurality of sense amplifiers, by providing different driving signals through nodes of different signal lines to the adjacent sense amplifiers.

### CROSS-REFERENCES TO RELATED APPLICATION

The present application claims priority under 35 U.S.C. § 119(a) to Korean application number 10-2021-0051054, filed on Apr. 20, 2021, in the Korean Intellectual Property Office, which is incorporated herein by reference in its entirety.

### BACKGROUND

### 1. Technical Field

Various embodiments generally relate to a semiconductor circuit, and more particularly, to a semiconductor apparatus including sense amplifiers.

### 2. Related Art

Memory cell structures of semiconductor apparatuses, for example, semiconductor memory apparatuses, may be generally divided into a folded bit line structure and an open bit line structure.

In the folded bit line structure, a bit line (hereinafter, referred to as a driving bit line) through which data is driven and a bit line (hereinafter, referred to as a reference bit line) which serves as a reference in an amplification operation are disposed in the same memory cell mat with respect to a sense amplifier circuit, that is, a bit line sense amplifier, disposed in a core region of a semiconductor apparatus. In the open bit line structure, a driving bit line and a reference bit line are disposed in different memory cell mats with respect to a bit line sense amplifier. Because noise generated in the driving bit line and noise generated in the reference bit line are different from each other, the open bit line structure is vulnerable to such noise. In the case of the folded bit line structure, a unit memory cell structure is designed as 8F2, and in the case of the open bit line structure, a unit memory cell structure is designed as 6F2 with a higher degree of integration than 8F2. Therefore, when considering the same data storage capacity, a semiconductor memory apparatus having the open bit line structure has a higher degree of integration than a semiconductor memory apparatus having the folded bit line structure.

Referring to FIG. 1, a conventional semiconductor apparatus 10 having an open bit line structure includes sense amplifier circuits 21 and 22 which are disposed between memory cell mats 11 to 13.

In the semiconductor apparatus 10 having an open bit line structure, driving bit lines BLi and BLj to perform sensing and amplification are disposed in a second memory cell mat 12, a reference bit line BLBi serving as a reference for the driving bit line BLi is disposed in a first memory cell mat 11, and a reference bit line BLBj serving as a reference for the driving bit line BLj is disposed in a third memory cell mat 13. The sense amplifier (SA) circuit 21 reads data stored in a corresponding memory cell MC by sensing and amplifying a level of the driving bit line BLi based on a voltage level of the reference bit line BLBi. The sense amplifier circuit 22 reads data stored in a corresponding memory cell MC by sensing and amplifying a level of the driving bit line BLj based on a voltage level of the reference bit line BLBj. In the semiconductor apparatus 10 having an open bit line structure, noise between adjacent bit lines may increase, which may degrade the operational performance of the semiconductor apparatus 10.

### SUMMARY

In an embodiment, a semiconductor apparatus may include: a plurality of bit lines; a plurality of sense amplifiers coupled to the plurality of bit lines, respectively, and configured to sense and amplify corresponding signals; and a sense amplifier driving signal providing circuit configured to drive adjacent sense amplifiers among the plurality of sense amplifiers, by providing different driving signals through nodes of different signal lines to the adjacent sense amplifiers.

In an embodiment, a semiconductor apparatus may include: a plurality of bit lines; a plurality of sense amplifiers coupled to the plurality of bit lines, divided into a plurality of sense amplifier groups, and each configured to sense and amplify a voltage difference between two bit lines coupled to a sense amplifier; and a sense amplifier driving signal providing circuit configured to provide a plurality of driving signal sets to the plurality of sense amplifier groups, respectively.

In an embodiment, a semiconductor apparatus may include: a first cell mat including a plurality of driving bit lines; a second cell mat including a plurality of reference bit lines; a plurality of sense amplifiers coupled to some of the plurality of driving bit lines and some of the plurality of reference bit lines, and each configured to sense and amplify a voltage difference between two bit lines coupled to a sense amplifier; and a sense amplifier driving signal providing circuit configured to drive adjacent sense amplifiers among the plurality of sense amplifiers, by providing different driving signals through nodes of different signal lines to the adjacent signal lines.

In an embodiment, a semiconductor apparatus may include: a first cell mat including a plurality of driving bit lines; a second cell mat including a plurality of reference bit lines; a plurality of sense amplifiers coupled to some of the plurality of driving bit lines and some of the plurality of reference bit lines, divided into a plurality of sense amplifier groups, and each configured to sense and amplify a voltage difference between two bit lines coupled to a sense amplifier; and a sense amplifier driving signal providing circuit configured to provide a plurality of driving signal sets to the plurality of sense amplifier groups, respectively.

### BRIEF DESCRIPTION OF THE DRAWINGS

FIG. 1 is a diagram illustrating a semiconductor apparatus having an open bit line structure according to the conventional art.

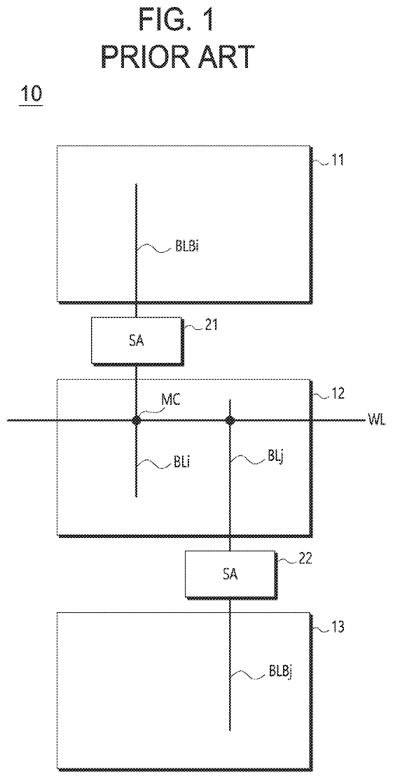

FIG. 2 is a diagram illustrating a configuration of a semiconductor apparatus in accordance with an embodiment.

FIG. 3 is a diagram illustrating a configuration of a semiconductor apparatus in accordance with an embodiment.

FIG. 4 is a diagram illustrating a configuration of a semiconductor apparatus in accordance with an embodiment.

FIG. 5 is a diagram illustrating a configuration of a semiconductor apparatus in accordance with an embodiment.

FIG. 6 is a diagram illustrating a configuration of a semiconductor apparatus in accordance with an embodiment.

FIG. 7 is a diagram illustrating a configuration of a semiconductor apparatus in accordance with an embodiment.

### DETAILED DESCRIPTION

Hereinafter, a semiconductor apparatus will be described below with reference to the accompanying drawings through various examples of embodiments.

Various embodiments are directed to a semiconductor apparatus capable of reducing noise between adjacent bit lines.

Adjacent sense amplifiers may be determined based on order of bit lines coupled thereto among the plurality of bit lines.

The sense amplifier driving signal providing circuit may include: a driver configured to output the different driving signals, generated by branching a signal generated in response to a sense amplifier control signal, to the different signal lines.

The sense amplifier driving signal providing circuit may include: a plurality of drivers configured to output the different driving signals, generated by using a first power source in response to a sense amplifier control signal, to the different signal lines.

The sense amplifier driving signal providing circuit may include: a plurality of drivers configured to output the different driving signals, generated by using a plurality of power sources in response to a sense amplifier control signal, to the different signal lines.

The plurality of sense amplifier groups may include a first sense amplifier group and a second sense amplifier group. The first sense amplifier group may be coupled to even-ordered bit lines among the plurality of bit lines, and the second sense amplifier group may be coupled to odd-ordered bit lines among the plurality of bit lines.

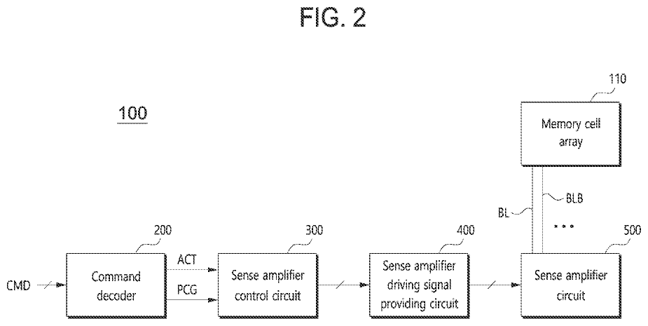

FIG. 2 is a diagram illustrating a configuration of a semiconductor apparatus 100 in accordance with an embodiment.

Referring to FIG. 2, the semiconductor apparatus 100 in accordance with an embodiment may include a command decoder 200, a sense amplifier control circuit 300, a sense amplifier driving signal providing circuit 400, a memory cell array 110 and a sense amplifier circuit 500.

The command decoder 200 may generate an active signal ACT and a precharge signal PCG in response to a command CMD. In addition to the active signal ACT and the precharge signal PCG, the command decoder 100 may generate a read signal, a refresh signal and so forth which are not shown. The sense amplifier control circuit 300 may generate a plurality of sense amplifier control signals in response to the active signal ACT and the precharge signal PCG. The sense amplifier driving signal providing circuit 400 may generate at least one driving signal set in response to the plurality of sense amplifier control signals output from the sense amplifier control circuit 300. The memory cell array 110 may have an open bit line structure. The memory cell array 110 may be divided into a plurality of cell mats. The memory cell array 110 may include at least one of a volatile memory and a nonvolatile memory. Examples of the volatile memory may include an SRAM (static RAM), a DRAM (dynamic RAM) and an SDRAM (synchronous DRAM). Examples of the nonvolatile memory may include a ROM (read only memory), a PROM (programmable ROM), an EEPROM (electrically erasable and programmable ROM), an EPROM (electrically programmable ROM), a flash memory, a PRAM (phase change RAM), an MRAM (magnetic RAM), an RRAM (resistive RAM) and an FRAM (ferroelectric RAM). The sense amplifier circuit 500 may include a plurality of sense amplifiers. The sense amplifier circuit 500 may be activated by being applied with the at least one driving signal set output from the sense amplifier driving signal providing circuit 400. An activated sense amplifier may sense and amplify a voltage difference between a driving bit line BL and a reference bit line BLB. In an embodiment, an activated sense amplifier may sense and amplify corresponding signals received from a driving bit line BL and a reference bit line BLB. For example, in an embodiment, an activated sense amplifier may sense and amplify a voltage difference between a corresponding signal of a driving bit line BL and a corresponding signal of a reference bit line BLB.

Adjacent sense amplifiers among the plurality of sense amplifiers of the sense amplifier circuit 500 may be configured to be provided with driving signals through nodes of different signal lines. The adjacent sense amplifiers may be determined based on the order of bit lines coupled to the adjacent sense amplifiers. Among the plurality of sense amplifiers, a first sense amplifier may be configured to be provided with a driving signal through a node of a first signal line, and a second sense amplifier adjacent to the first sense amplifier may be configured to be provided with a driving signal through a node of a second signal line. Also, a third sense amplifier adjacent to the second sense amplifier may be configured to be provided with a driving signal through a node of the first signal line or be provided with a driving signal through a node of a third signal line.

The plurality of sense amplifiers of the sense amplifier circuit 500 may be divided into a plurality of groups, and each group may be driven according to a separate driving signal set provided through a separate signal line set. For example, when the plurality of sense amplifiers of the sense amplifier circuit 500 are divided into a first group and a second group, the first group may be driven according to a first driving signal set, and the second group may be driven according to a second driving signal set. The first group may be sense amplifiers which are coupled to even-ordered bit lines, and the second group may be sense amplifiers which are coupled to odd-ordered bit lines.

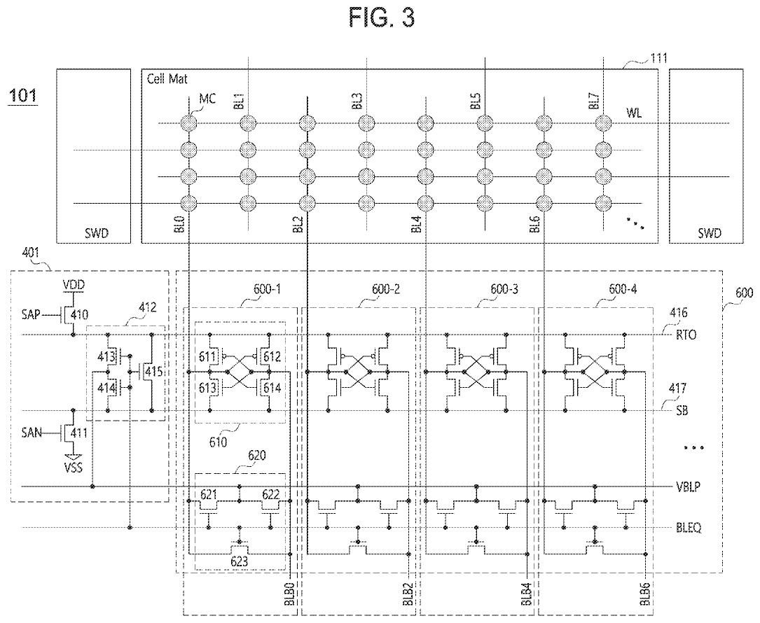

FIG. 3 is a diagram illustrating a configuration of a semiconductor apparatus 101 in accordance with an embodiment. FIG. 3 illustrates a configuration example of some of the components of the semiconductor apparatus 100 of FIG. 2, for example, the sense amplifier driving signal providing circuit 400, the memory cell array 110 and the sense amplifier circuit 500.

Referring to FIG. 3, the semiconductor apparatus 101 in accordance with an embodiment may include a cell mat 111, a sense amplifier driving signal providing circuit 401 and a sense amplifier circuit 600. The semiconductor apparatus 101 may further include word line drivers SWD for driving word lines WL of the cell mat 111 depending on a row address decoding result.

Since the cell mat 111 is a part of the memory cell array 110 of FIG. 2, the cell mat 111 may be configured to have an open bit line structure in the same manner as the memory cell array 110. The cell mat 111 may include a plurality of memory cells MC, and a plurality of bit lines BL0 to BL7 and a plurality of word lines WL which are coupled to the plurality of memory cells MC. Since the cell mat 111 has the open bit line structure, some driving bit lines BL0, BL2, BL4 and BL6 among the plurality of bit lines BL0 to BL7 of the upper cell mat 111 with respect to the sense amplifier circuit 600 and some reference bit lines BLB0, BLB2, BLB4 and BLB6 among a plurality of bit lines BLB0 to BLB7 of a lower cell mat (not illustrated) with respect to the sense amplifier circuit 600 may be coupled to the sense amplifier circuit 600. The remaining driving bit lines BL1, BL3, BL5 and BL7 among the plurality of bit lines BL0 to BL7 may be coupled to an upper sense amplifier circuit (not illustrated) with respect to the upper cell mat 111.

The sense amplifier driving signal providing circuit 401 may generate a driving signal set RTO and SB in response to sense amplifier control signals SAP and SAN output from the sense amplifier control circuit 300, and may apply the generated driving signal set RTO and SB to a signal line set 416 and 417. The sense amplifier driving signal providing circuit 401 may precharge the driving signal set RTO and SB to the level of a bit line precharge voltage VBLP in response to a bit line equalization signal BLEQ.

The sense amplifier driving signal providing circuit 401 may include a first driver 410, a second driver 411 and a precharge circuit 412.

The first driver 410 may generate a first driving signal RTO of the driving signal set RTO and SB by using a power supply voltage VDD in response to a first sense amplifier control signal SAP, and may apply the first driving signal RTO to a first signal line 416. The first driver 410 may generate the power supply voltage VDD as the first driving signal RTO when the first sense amplifier control signal SAP has a high level. The first driver 410 may be configured by a transistor. The transistor may have a source terminal to which the power supply voltage VDD is applied, a gate terminal to which the first sense amplifier control signal SAP is input and a drain terminal which is coupled to the first signal line 416.

The second driver 411 may generate a second driving signal SB of the driving signal set RTO and SB by using a ground voltage VSS in response to a second sense amplifier control signal SAN, and may apply the second driving signal SB to a second signal line 417. The second driver 411 may generate the ground voltage VSS as the second driving signal SB when the second sense amplifier control signal SAN has a high level. The second driver 411 may be configured by a transistor. The transistor may have a source terminal to which the ground voltage VSS is applied, a gate terminal to which the second sense amplifier control signal SAN is input and a drain terminal which is coupled to the second signal line 417.

The precharge circuit 412 may precharge the driving signal set RTO and SB to the level of the bit line precharge voltage VBLP in response to the bit line equalization signal BLEQ. The precharge circuit 412 may include first to third transistors 413 to 415. The first transistor 413 may have a drain terminal which receives the first driving signal RTO through the first signal line 416 and a source terminal to which the bit line precharge voltage VBLP is applied. The second transistor 414 may have a drain terminal which receives the second driving signal SB through the second signal line 417 and a source terminal to which the bit line precharge voltage VBLP is applied. The third transistor 415 may have a drain terminal which receives the first driving signal RTO through the first signal line 416 and a source terminal which receives the second driving signal SB through the second signal line 417. The bit line equalization signal BLEQ may be input in common to gate terminals of the first to third transistors 413 to 415.

The sense amplifier circuit 600 may include a plurality of sense amplifiers 600-1 to 600-4. Adjacent sense amplifiers among the plurality of sense amplifiers 600-1 to 600-4 may be configured to receive driving signals through nodes of different signal lines. The plurality of sense amplifiers 600-1 to 600-4 may receive in common the first driving signal RTO through the first signal line 416, may receive in common the second driving signal SB through the second signal line 417, and may sense and amplify voltage level differences between the driving bit lines BL0, BL2, BL4 and BL6 and the reference bit lines BLB0, BLB2, BLB4 and BLB6 in response to the first driving signal RTO and the second driving signal SB. The plurality of sense amplifiers 600-1 to 600-4 may precharge the driving bit lines BL0, BL2, BL4 and BL6 and the reference bit lines BLB0, BLB2, BLB4 and BLB6 to the level of the bit line precharge voltage VBLP in response to the bit line equalization signal BLEQ. The plurality of sense amplifiers 600-1 to 600-4 may be configured in the same manner as one another.

A first sense amplifier 600-1 may sense and amplify a voltage level difference between the driving bit line BL0 and the reference bit line BLB0 in response to the first driving signal RTO and the second driving signal SB. The first sense amplifier 600-1 may include a sensing unit 610 and a precharge circuit 620. The sensing unit 610 may include first to fourth transistors 611 to 614 having a cross-coupled structure. The first transistor 611 may have a source terminal which receives the first driving signal RTO through the first signal line 416 and a drain terminal which is coupled to the driving bit line BL0. The second transistor 612 may have a source terminal which receives the first driving signal RTO through the first signal line 416 and a drain terminal which is coupled to the reference bit line BLB0. The third transistor 613 may have a source terminal which receives the second driving signal SB through the second signal line 417 and a drain terminal which is coupled to the driving bit line BL0. The fourth transistor 614 may have a source terminal which receives the second driving signal SB through the second signal line 417 and a drain terminal which is coupled to the reference bit line BLB0. A gate terminal of the first transistor 611 and a gate terminal of the third transistor 613 may be coupled to the reference bit line BLB0. A gate terminal of the second transistor 612 and a gate terminal of the fourth transistor 614 may be coupled to the driving bit line BLB0. The precharge circuit 620 may include first to third transistors 621 to 623. The first transistor 621 may have a drain terminal which is coupled to the driving bit line BL0 and a source terminal to which the bit line precharge voltage VBLP is applied. The second transistor 622 may have a drain terminal which is coupled to the reference bit line BLB0 and a source terminal to which the bit line precharge voltage VBLP is applied. The third transistor 623 may have a drain terminal which is coupled to the driving bit line BL0 and a source terminal which is coupled to the reference bit line BLB0. The bit line equalization signal BLEQ may be input in common to gate terminals of the first to third transistors 621 to 623.

A second sense amplifier 600-2 may sense and amplify a voltage level difference between the driving bit line BL2 and the reference bit line BLB2 in response to the first driving signal RTO and the second driving signal SB. The third sense amplifier 600-3 may sense and amplify a voltage level difference between the driving bit line BL4 and the reference bit line BLB4 in response to the first driving signal RTO and the second driving signal SB. The fourth sense amplifier 600-4 may sense and amplify a voltage level difference between the driving bit line BL6 and the reference bit line BLB6 in response to the first driving signal RTO and the second driving signal SB.

The numbers of memory cells, bit lines, word lines and sense amplifiers according to FIG. 3 described above are only according to an example of an embodiment and are not limited, and may vary according to memory capacity and a design method.

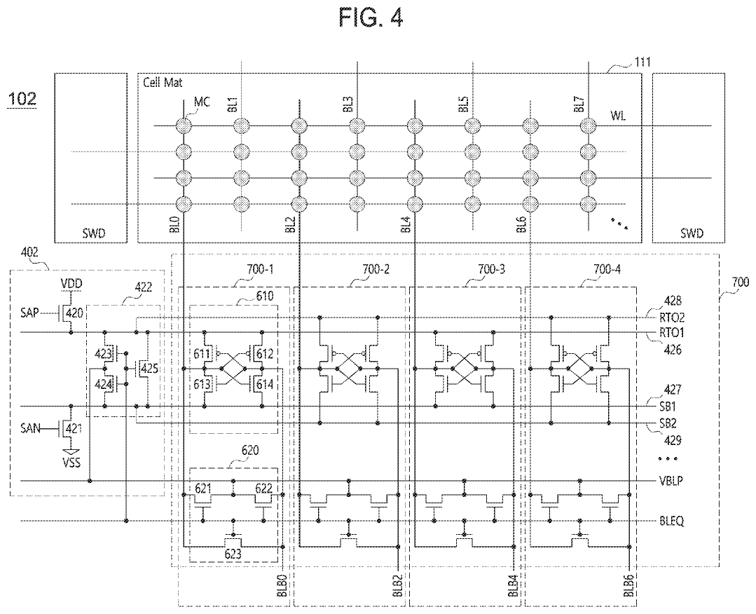

FIG. 4 is a diagram illustrating a configuration of a semiconductor apparatus 102 in accordance with an embodiment.

Referring to FIG. 4, the semiconductor apparatus 102 in accordance with the embodiment may include a cell mat 111, a sense amplifier driving signal providing circuit 402 and a sense amplifier circuit 700. The semiconductor apparatus 102 may further include word line drivers SWD for driving word lines WL of the cell mat 111 depending on a row address decoding result.

The cell mat 111 may be configured in the same manner as in FIG. 3. Since the cell mat 111 has an open bit line structure, some driving bit lines BL0, BL2, BL4 and BL6 among a plurality of bit lines BL0 to BL7 of the upper cell mat 111 with respect to the sense amplifier circuit 700 and some reference bit lines BLB0, BLB2, BLB4 and BLB6 among a plurality of bit lines BLB0 to BLB7 of a lower cell mat (not illustrated) with respect to the sense amplifier circuit 700 may be coupled to the sense amplifier circuit 700. The remaining driving bit lines BL1, BL3, BL5 and BL7 among the plurality of bit lines BL0 to BL7 may be coupled to an upper sense amplifier circuit (not illustrated) with respect to the upper cell mat 111. Hereinafter, a first group including the even-ordered driving bit lines BL0 and BL4 among the some driving bit lines BL0, BL2, BL4 and BL6 will be referred to as even driving bit lines, and a second group including the odd-ordered driving bit lines BL2 and BL6 among the some driving bit lines BL0, BL2, BL4 and BL6 will be referred to as odd driving bit lines. Also, a first group including the even-ordered reference bit lines BLB0 and BLB4 among the some reference bit lines BLB0, BLB2, BLB4 and BLB6 will be referred to as even reference bit lines, and a second group including the odd-ordered reference bit lines BLB2 and BLB6 among the some reference bit lines BLB0, BLB2, BLB4 and BLB6 will be referred to as odd reference bit lines. For example, a first bit line, that is, the first driving bit line BL0, may be an even driving bit line, and a second bit line, that is, the second driving bit line BL2, may be an odd driving bit line.

The sense amplifier driving signal providing circuit 402 may generate a first driving signal set RTO1 and SB1 and a second driving signal set RTO2 and SB2 in response to sense amplifier control signals SAP and SAN output from the sense amplifier control circuit 300, may apply the first driving signal set RTO1 and SB1 to a first signal line set 426 and 427, and may apply the second driving signal set RTO2 and SB2 to a second signal line set 428 and 429. Hereinafter, a driving signal RTO1 of the first driving signal set RTO1 and SB1 may be referred to as a first driving signal RTO1, and a driving signal SB1 of the first driving signal set RTO1 and SB1 may be referred to as a second driving signal SB1. A driving signal RTO2 of the second driving signal set RTO2 and SB2 may be referred to as a third driving signal RTO2, and a driving signal SB2 of the second driving signal set RTO2 and SB2 may be referred to as a fourth driving signal SB2. A signal line 426 of the first signal line set 426 and 427 may be referred to as a first signal line 426, and a signal line 427 of the first signal line set 426 and 427 may be referred to as a second signal line 427. A signal line 428 of the second signal line set 428 and 429 may be referred to as a third signal line 428, and a signal line 429 of the second signal line set 428 and 429 may be referred to as a fourth signal line 429.

The sense amplifier driving signal providing circuit 402 may precharge the first driving signal set RTO1 and SB1 and the second driving signal set RTO2 and SB2 to the level of a bit line precharge voltage VBLP in response to a bit line equalization signal BLEQ.

The sense amplifier driving signal providing circuit 402 may include a first driver 420, a second driver 421 and a precharge circuit 422.

The first driver 420 may generate the first driving signal RTO1 and the third driving signal RTO2 in response to a first sense amplifier control signal SAP, may apply the first driving signal RTO1 to the first signal line 426, and may apply the third driving signal RTO2 to the third signal line 428 branched from the first signal line 426. The first driver 420 may be configured by a transistor. The transistor may have a source terminal to which a power supply voltage VDD is applied, a gate terminal to which the first sense amplifier control signal SAP is input and a drain terminal which is coupled to the first signal line 426. The first driver 420 may generate the power supply voltage VDD as the first driving signal RTO1 and the third driving signal RTO2 when the first sense amplifier control signal SAP has a high level.

The second driver 421 may generate the second driving signal SB1 and the fourth driving signal SB2 in response to a second sense amplifier control signal SAN, may apply the second driving signal SB1 to the second signal line 427, and may apply the fourth driving signal SB2 to the fourth signal line 429 branched from the second signal line 427. The second driver 421 may be configured by a transistor. The transistor may have a source terminal to which a ground voltage VSS is applied, a gate terminal to which the second sense amplifier control signal SAN is input and a drain terminal which is coupled to the second signal line 427. The second driver 421 may generate the ground voltage VSS as the second driving signal SB1 and the fourth driving signal SB2 when the second sense amplifier control signal SAN has a high level.

The precharge circuit 422 may precharge the first driving signal set RTO1 and SB1 and the second driving signal set RTO2 and SB2 to the level of the bit line precharge voltage VBLP in response to the bit line equalization signal BLEQ. The precharge circuit 422 may include first to third transistors 423 to 425. The first transistor 423 may have a drain terminal which receives the first driving signal RTO1 and the third driving signal RTO2 through the first signal line 426 and the third signal line 428 and a source terminal to which the bit line precharge voltage VBLP is applied. The second transistor 424 may have a drain terminal which receives the second driving signal SB1 and the fourth driving signal SB2 through the second signal line 427 and the fourth signal line 429 and a source terminal to which the bit line precharge voltage VBLP is applied. The third transistor 425 may have a drain terminal which receives the first driving signal RTO1 and the third driving signal RTO2 through the first signal line 426 and the third signal line 428 and a source terminal which receives the second driving signal SB1 and the fourth driving signal SB2 through the second signal line 427 and the fourth signal line 429. The bit line equalization signal BLEQ may be input in common to gate terminals of the first to third transistors 423 to 425.

The sense amplifier circuit 700 may include a plurality of sense amplifiers 700-1 to 700-4. The circuit configuration of the plurality of sense amplifiers 700-1 to 700-4 may be the same as that in FIG. 3. Adjacent sense amplifiers among the plurality of sense amplifiers 700-1 to 700-4 may be configured to receive driving signals through nodes of different signal lines. The adjacent sense amplifiers may be determined based on the order of bit lines coupled to the adjacent sense amplifiers. Among the plurality of sense amplifiers 700-1 to 700-4, the sense amplifiers 700-1 and 700-3 which are coupled to the even driving bit lines BL0 and BL4 and the even reference bit lines BLB0 and BLB4 may be driven in response to the first driving signal set RTO1 and SB1. Among the plurality of sense amplifiers 700-1 to 700-4, the sense amplifiers 700-2 and 700-4 which are coupled to the odd driving bit lines BL2 and BL6 and the odd reference bit lines BLB2 and BLB6 may be driven in response to the second driving signal set RTO2 and SB2. The plurality of sense amplifiers 700-1 to 700-4 may precharge the driving bit lines BL0, BL2, BL4 and BL6 and the reference bit lines BLB0, BLB2, BLB4 and BLB6 to the level of the bit line precharge voltage VBLP in response to the bit line equalization signal BLEQ.

A first sense amplifier 700-1 may sense and amplify a voltage level difference between the first even driving bit line BL0 and the first even reference bit line BLB0 in response to the first driving signal RTO1 and the second driving signal SB1. A second sense amplifier 700-2 may sense and amplify a voltage level difference between the first odd driving bit line BL2 and the first odd reference bit line BLB2 in response to the third driving signal RTO2 and the fourth driving signal SB2. A third sense amplifier 700-3 may sense and amplify a voltage level difference between the second even driving bit line BL4 and the second even reference bit line BLB4 in response to the first driving signal RTO1 and the second driving signal SB1. A fourth sense amplifier 700-4 may sense and amplify a voltage level difference between the second odd driving bit line BL6 and the second odd reference bit line BLB6 in response to the third driving signal RTO2 and the fourth driving signal SB2.

The numbers of memory cells, bit lines, word lines and sense amplifiers according to FIG. 4 described above are only according to an example of an embodiment and are not limited, and may vary according to memory capacity and a design method. In the above-described embodiment, a plurality of sense amplifiers are divided based on a first group including even-ordered bit lines and a second group including odd-ordered bit lines, and divided sense amplifier groups are activated by the first driving signal set RTO1 and SB1 and the second driving signal set RTO2 and SB2, respectively, provided through separate signal lines, which makes it possible to reduce noise between adjacent bit lines.

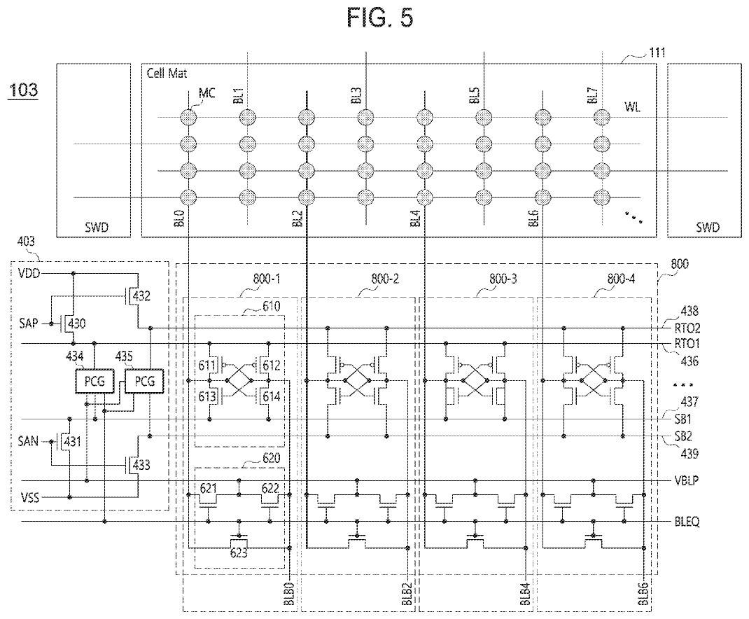

FIG. 5 is a diagram illustrating a configuration of a semiconductor apparatus 103 in accordance with an embodiment.

Referring to FIG. 5, the semiconductor apparatus 103 in accordance with the embodiment may include a cell mat 111, a sense amplifier driving signal providing circuit 403 and a sense amplifier circuit 800. The semiconductor apparatus 103 may further include word line drivers SWD for driving word lines WL of the cell mat 111 depending on a row address decoding result.

The cell mat 111 may be configured in the same manner as in FIG. 4.

The sense amplifier driving signal providing circuit 403 may generate respective signals of a first driving signal set RTO1 and SB1 and a second driving signal set RTO2 and SB2, by using separate drivers, in response to sense amplifier control signals SAP and SAN output from the sense amplifier control circuit 300, may apply the first driving signal set RTO1 and SB1 to a first signal line set 436 and 437, and may apply the second driving signal set RTO2 and SB2 to a second signal line set 438 and 439. A signal line 436 of the first signal line set 436 and 437 may be referred to as a first signal line 436, and a signal line 437 of the first signal line set 436 and 437 may be referred to as a second signal line 437. A signal line 438 of the second signal line set 438 and 439 may be referred to as a third signal line 438, and a signal line 439 of the second signal line set 438 and 439 may be referred to as a fourth signal line 439. The sense amplifier driving signal providing circuit 403 may precharge the first driving signal set RTO1 and SB1 and the second driving signal set RTO2 and SB2 to the level of a bit line precharge voltage VBLP in response to a bit line equalization signal BLEQ.

The sense amplifier driving signal providing circuit 403 may include a first driver 430, a second driver 431, a third driver 432, a fourth driver 433, a first precharge circuit 434 and a second precharge circuit 435.

The first driver 430 may generate a first driving signal RTO1 in response to a first sense amplifier control signal SAP, and may apply the first driving signal RTO1 to the first signal line 436. The first driver 430 may be configured by a transistor. The transistor may have a source terminal to which a power supply voltage VDD is applied, a gate terminal to which the first sense amplifier control signal SAP is input and a drain terminal which is coupled to the first signal line 436. The first driver 430 may output the power supply voltage VDD as the first driving signal RTO1 when the first sense amplifier control signal SAP has a high level. The second driver 431 may generate a second driving signal SB1 in response to a second sense amplifier control signal SAN, and may apply the second driving signal SB1 to the second signal line 437.

The second driver 431 may be configured by a transistor. The transistor may have a source terminal to which a ground voltage VSS is applied, a gate terminal to which the second sense amplifier control signal SAN is input and a drain terminal which is coupled to the second signal line 437. The second driver 431 may output the ground voltage VSS as the second driving signal SB1 when the second sense amplifier control signal SAN has a high level.

The third driver 432 may generate a third driving signal RTO2 in response to the first sense amplifier control signal SAP, and may apply the third driving signal RTO2 to the third signal line 438. The third driver 432 may be configured by a transistor. The transistor may have a source terminal to which the power supply voltage VDD is applied, a gate terminal to which the first sense amplifier control signal SAP is input and a drain terminal which is coupled to the third signal line 438. The third driver 432 may output the power supply voltage VDD as the third driving signal RTO2 when the first sense amplifier control signal SAP has a high level.

The fourth driver 433 may generate a fourth driving signal SB2 in response to the second sense amplifier control signal SAN, and may apply the fourth driving signal SB2 to the fourth signal line 439. The fourth driver 433 may be configured by a transistor. The transistor may have a source terminal to which the ground voltage VSS is applied, a gate terminal to which the second sense amplifier control signal SAN is input and a drain terminal which is coupled to the fourth signal line 439. The fourth driver 433 may output the ground voltage VSS as the fourth driving signal SB2 when the second sense amplifier control signal SAN has a high level.

The first precharge circuit 434 may precharge the first driving signal set RTO1 and SB1 to the level of the bit line precharge voltage VBLP in response to the bit line equalization signal BLEQ. The first precharge circuit 434 may be configured in the same manner as the precharge circuit 412 in FIG. 4.

The second precharge circuit 435 may precharge the second driving signal set RTO2 and SB2 to the level of the bit line precharge voltage VBLP in response to the bit line equalization signal BLEQ. The second precharge circuit 435 may be configured in the same manner as in FIG. 4.

The sense amplifier circuit 800 may include a plurality of sense amplifiers 800-1 to 800-4. The circuit configuration of the plurality of sense amplifiers 800-1 to 800-4 may be the same as that in FIG. 4. Adjacent sense amplifiers among the plurality of sense amplifiers 800-1 to 800-4 may be configured to receive driving signals through nodes of different signal lines. The adjacent sense amplifiers may be determined based on the order of bit lines coupled to the adjacent sense amplifiers. Among the plurality of sense amplifiers 800-1 to 800-4, the sense amplifiers 800-1 and 800-3 which are coupled to even driving bit lines BL0 and BL4 and even reference bit lines BLB0 and BLB4 may be driven in response to the first driving signal set RTO1 and SB1. Among the plurality of sense amplifiers 800-1 to 800-4, the sense amplifiers 800-2 and 800-4 which are coupled to odd driving bit lines BL2 and BL6 and odd reference bit lines BLB2 and BLB6 may be driven in response to the second driving signal set RTO2 and SB2. The plurality of sense amplifiers 800-1 to 800-4 may precharge the driving bit lines BL0, BL2, BL4 and BL6 and the reference bit lines BLB0, BLB2, BLB4 and BLB6 to the level of the bit line precharge voltage VBLP in response to the bit line equalization signal BLEQ.

A first sense amplifier 800-1 may sense and amplify a voltage level difference between a first even driving bit line BL0 and a first even reference bit line BLB0 in response to the first driving signal RTO1 and the second driving signal SB1. A second sense amplifier 800-2 may sense and amplify a voltage level difference between a first odd driving bit line BL2 and a first odd reference bit line BLB2 in response to the third driving signal RTO2 and the fourth driving signal SB2. A third sense amplifier 800-3 may sense and amplify a voltage level difference between a second even driving bit line BL4 and a second even reference bit line BLB4 in response to the first driving signal RTO1 and the second driving signal SB1. A fourth sense amplifier 800-4 may sense and amplify a voltage level difference between a second odd driving bit line BL6 and a second odd reference bit line BLB6 in response to the third driving signal RTO2 and the fourth driving signal SB2.

The numbers of memory cells, bit lines, word lines and sense amplifiers according to FIG. 5 described above are only according to an example of an embodiment and are not limited, and may vary according to memory capacity and a design method. In the above-described embodiment, a plurality of sense amplifiers are divided based on a first group including even-ordered bit lines and a second group including odd-ordered bit lines, and divided sense amplifier groups are activated by the first driving signal set RTO1 and SB1 and the second driving signal set RTO2 and SB2, respectively, generated by using separate drivers, which makes it possible to reduce noise between adjacent bit lines.

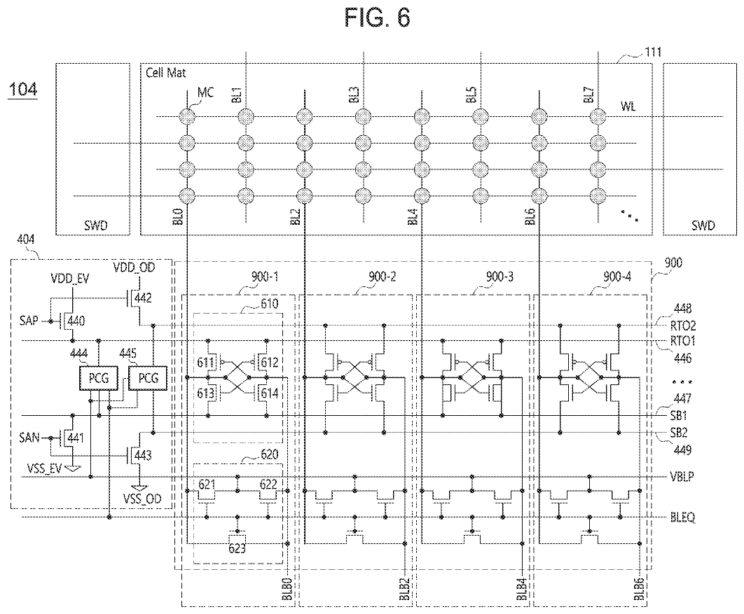

FIG. 6 is a diagram illustrating a configuration of a semiconductor apparatus 104 in accordance with an embodiment.

Referring to FIG. 6, the semiconductor apparatus 104 in accordance with the embodiment may include a cell mat 111, a sense amplifier driving signal providing circuit 404 and a sense amplifier circuit 900. The semiconductor apparatus 104 may further include word line drivers SWD for driving word lines WL of the cell mat 111 depending on a row address decoding result.

The cell mat 111 may be configured in the same manner as in FIG. 4.

The sense amplifier driving signal providing circuit 404 may generate respective signals of a first driving signal set RTO1 and SB1 and a second driving signal set RTO2 and SB2, by using separate drivers and separate power sources, in response to sense amplifier control signals SAP and SAN output from the sense amplifier control circuit 300, may apply the first driving signal set RTO1 and SB1 to a first signal line set 446 and 447, and may apply the second driving signal set RTO2 and SB2 to a second signal line set 448 and 449. A signal line 446 of the first signal line set 446 and 447 may be referred to as a first signal line 446, and a signal line 447 of the first signal line set 446 and 447 may be referred to as a second signal line 447. A signal line 448 of the second signal line set 448 and 449 may be referred to as a third signal line 448, and a signal line 449 of the second signal line set 448 and 449 may be referred to as a fourth signal line 449. The sense amplifier driving signal providing circuit 404 may precharge the first driving signal set RTO1 and SB1 and the second driving signal set RTO2 and SB2 to the level of a bit line precharge voltage VBLP in response to a bit line equalization signal BLEQ.

The sense amplifier driving signal providing circuit 404 may include a first driver 440, a second driver 441, a third driver 442, a fourth driver 443, a first precharge circuit 444 and a second precharge circuit 445.

The first driver 440 may generate a first driving signal RTO1 in response to a first sense amplifier control signal SAP, and may apply the first driving signal RTO1 to the first signal line 446. The first driver 440 may be configured by a transistor. The transistor may have a source terminal to which a first power supply voltage VDD_EV is applied, a gate terminal to which the first sense amplifier control signal SAP is input and a drain terminal which is coupled to the first signal line 446. The first driver 440 may output the first power supply voltage VDD_EV as the first driving signal RTO1 when the first sense amplifier control signal SAP has a high level.

The second driver 441 may generate a second driving signal SB1 in response to a second sense amplifier control signal SAN, and may apply the second driving signal SB1 to the second signal line 447. The second driver 441 may be configured by a transistor. The transistor may have a source terminal to which a first ground voltage VSS_EV is applied, a gate terminal to which the second sense amplifier control signal SAN is input and a drain terminal which is coupled to the second signal line 447. The second driver 441 may output the first ground voltage VSS_EV as the second driving signal SB1 when the second sense amplifier control signal SAN has a high level.

The third driver 442 may generate a third driving signal RTO2 in response to the first sense amplifier control signal SAP, and may apply the third driving signal RTO2 to the third signal line 448. The third driver 442 may be configured by a transistor. The transistor may have a source terminal to which a second power supply voltage VDD_OD is applied, a gate terminal to which the first sense amplifier control signal SAP is input and a drain terminal which is coupled to the third signal line 448. The third driver 442 may output the second power supply voltage VDD_OD as the third driving signal RTO2 when the first sense amplifier control signal SAP has a high level.

The fourth driver 443 may generate a fourth driving signal SB2 in response to the second sense amplifier control signal SAN, and may apply the fourth driving signal SB2 to the fourth signal line 449. The fourth driver 443 may be configured by a transistor. The transistor may have a source terminal to which a second ground voltage VSS_OD is applied, a gate terminal to which the second sense amplifier control signal SAN is input and a drain terminal which is coupled to the fourth signal line 449. The fourth driver 443 may output the second ground voltage VSS_OD as the fourth driving signal SB2 when the second sense amplifier control signal SAN has a high level.

The first precharge circuit 444 may precharge the first driving signal set RTO1 and SB1 to the level of the bit line precharge voltage VBLP in response to the bit line equalization signal BLEQ. The first precharge circuit 444 may be configured in the same manner as the precharge circuit 412 in FIG. 3.

The second precharge circuit 445 may precharge the second driving signal set RTO2 and SB2 to the level of the bit line precharge voltage VBLP in response to the bit line equalization signal BLEQ. The second precharge circuit 445 may be configured in the same manner as in FIG. 4.

The sense amplifier circuit 900 may include a plurality of sense amplifiers 900-1 to 900-4. The circuit configuration of the plurality of sense amplifiers 900-1 to 900-4 may be the same as that in FIG. 4. Adjacent sense amplifiers among the plurality of sense amplifiers 900-1 to 900-4 may be configured to receive driving signals through nodes of different signal lines. The adjacent sense amplifiers may be determined based on the order of bit lines coupled to the adjacent sense amplifiers. Among the plurality of sense amplifiers 900-1 to 900-4, the sense amplifiers 900-1 and 900-3 which are coupled to even driving bit lines BL0 and BL4 and even reference bit lines BLB0 and BLB4 may be driven in response to the first driving signal set RTO1 and SB1. Among the plurality of sense amplifiers 900-1 to 900-4, the sense amplifiers 900-2 and 900-4 which are coupled to odd driving bit lines BL2 and BL6 and odd reference bit lines BLB2 and BLB6 may be driven in response to the second driving signal set RTO2 and SB2. The plurality of sense amplifiers 900-1 to 900-4 may precharge the driving bit lines BL0, BL2, BL4 and BL6 and the reference bit lines BLB0, BLB2, BLB4 and BLB6 to the level of the bit line precharge voltage VBLP in response to the bit line equalization signal BLEQ.

The numbers of memory cells, bit lines, word lines and sense amplifiers according to FIG. 6 described above are only according to an example of an embodiment and are not limited, and may vary according to memory capacity and a design method. In the above-described embodiment, a plurality of sense amplifiers are divided based on a first group including even-ordered bit lines and a second group including odd-ordered bit lines, and divided sense amplifier groups are driven by the first driving signal set RTO1 and SB1 and the second driving signal set RTO2 and SB2, respectively, generated by using separate drivers and separate power sources, which makes it possible to reduce noise between adjacent bit lines.

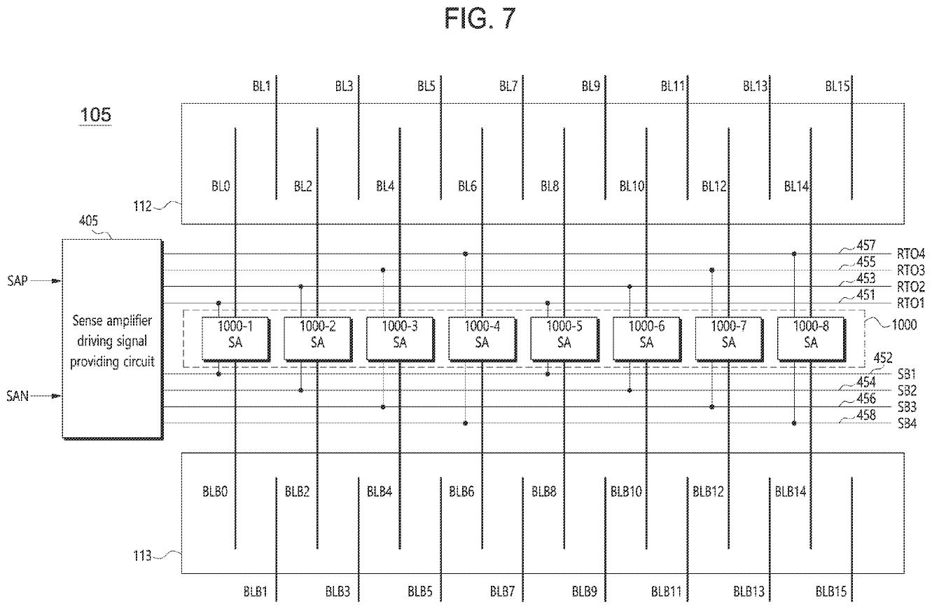

FIG. 7 is a diagram illustrating a configuration of a semiconductor apparatus 105 in accordance with an embodiment.

Referring to FIG. 7, the semiconductor apparatus 105 in accordance with the embodiment may include a first cell mat 112, a second cell mat 113, a sense amplifier driving signal providing circuit 405 and a sense amplifier circuit 1000.

Since the first cell mat 112 is a part of the memory cell array 110 of FIG. 2, the first cell mat 112 may be configured to have an open bit line structure in the same manner as the memory cell array 110. The first cell mat 112 may include a plurality of driving bit lines BL0 to BL15. Although not illustrated, the first cell mat 112 may further include a plurality of memory cells MC and a plurality of word lines WL which are coupled to the plurality of memory cells MC. Since the first cell mat 112 has the open bit line structure, some driving bit lines BL0, BL2, BL4, BL6, BL8, BL10, BL12 and BL14 among the plurality of driving bit lines BL0 to BL15 may be coupled to the sense amplifier circuit 1000.

The second cell mat 113 may also be configured to have an open bit line structure. The second cell mat 113 may include a plurality of reference bit lines BLB0 to BLB15. Although not illustrated, the second cell mat 113 may further include a plurality of memory cells MC and a plurality of word lines WL which are coupled to the plurality of memory cells MC. Since the second cell mat 113 has the open bit line structure, some reference bit lines BLB0, BLB2, BLB4, BLB6, BLB8, BLB10, BLB12 and BLB14 among the plurality of reference bit lines BLB0 to BLB15 may be coupled to the sense amplifier circuit 1000.

The sense amplifier driving signal providing circuit 405 may generate a first driving signal set RTO1 and SB1, a second driving signal set RTO2 and SB2, a third driving signal set RTO3 and SB3 and a fourth driving signal set RTO4 and SB4 in response to sense amplifier control signals SAP and SAN output from the sense amplifier control circuit 300. The sense amplifier driving signal providing circuit 405 may apply the first driving signal set RTO1 and SB1 to a first signal line set 451 and 452, may apply the second driving signal set RTO2 and SB2 to a second signal line set 453 and 454, may apply the third driving signal set RTO3 and SB3 to a third signal line set 455 and 456, and may apply the fourth driving signal set RTO4 and SB4 to a fourth signal line set 457 and 458. A driving signal RTO1 of the first driving signal set RTO1 and SB1 may be referred to as a first driving signal RTO1, and a driving signal SB1 of the first driving signal set RTO1 and SB1 may be referred to as a second driving signal SB1. A driving signal RTO2 of the second driving signal set RTO2 and SB2 may be referred to as a third driving signal RTO2, and a driving signal SB2 of the second driving signal set RTO2 and SB2 may be referred to as a fourth driving signal SB2. A driving signal RTO3 of the third driving signal set RTO3 and SB3 may be referred to as a fifth driving signal RTO3, and a driving signal SB3 of the third driving signal set RTO3 and SB3 may be referred to as a sixth driving signal SB3. A driving signal RTO4 of the fourth driving signal set RTO4 and SB4 may be referred to as a seventh driving signal RTO4, and a driving signal SB4 of the fourth driving signal set RTO4 and SB4 may be referred to as an eighth driving signal SB4. A signal line 451 of the first signal line set 451 and 452 may be referred to as a first signal line 451, and a signal line 452 of the first signal line set 451 and 452 may be referred to as a second signal line 452. A signal line 453 of the second signal line set 453 and 454 may be referred to as a third signal line 453, and a signal line 454 of the second signal line set 453 and 454 may be referred to as a fourth signal line 454. A signal line 455 of the third signal line set 455 and 456 may be referred to as a fifth signal line 455, and a signal line 456 of the third signal line set 455 and 456 may be referred to as a sixth signal line 456. A signal line 457 of the fourth signal line set 457 and 458 may be referred to as a seventh signal line 457, and a signal line 458 of the fourth signal line set 457 and 458 may be referred to as an eighth signal line 458. The sense amplifier driving signal providing circuit 405 may precharge the first driving signal set RTO1 and SB1, the second driving signal set RTO2 and SB2, the third driving signal set RTO3 and SB3 and the fourth driving signal set RTO4 and SB4 to the level of a bit line precharge voltage VBLP in response to a bit line equalization signal BLEQ.

The sense amplifier driving signal providing circuit 405 may be configured in the same form as the sense amplifier driving signal providing circuit 402 of FIG. 4, the sense amplifier driving signal providing circuit 403 of FIG. 5 or the sense amplifier driving signal providing circuit 404 of FIG. 6.

When the sense amplifier driving signal providing circuit 405 is configured in the same form as the sense amplifier driving signal providing circuit 402 of FIG. 4, the sense amplifier driving signal providing circuit 405 may generate the first driving signal RTO1, the third driving signal RTO2, the fifth driving signal RTO3 and the seventh driving signal RTO4 by branching a signal generated by driving a power supply voltage using one driver according to a first sense amplifier control signal SAP. Further, the sense amplifier driving signal providing circuit 405 may generate the second driving signal SB1, the fourth driving signal SB2, the sixth driving signal SB3 and the eighth driving signal SB4 by branching a signal generated by driving a ground voltage using one driver according to a second sense amplifier control signal SAN.

When the sense amplifier driving signal providing circuit 405 is configured in the same form as the sense amplifier driving signal providing circuit 403 of FIG. 5, the sense amplifier driving signal providing circuit 405 may generate the first driving signal RTO1, the third driving signal RTO2, the fifth driving signal RTO3 and the seventh driving signal RTO4 by driving a power supply voltage using four drivers according to the first sense amplifier control signal SAP. Further, the sense amplifier driving signal providing circuit 405 may generate the second driving signal SB1, the fourth driving signal SB2, the sixth driving signal SB3 and the eighth driving signal SB4 by driving a ground voltage using four drivers according to the second sense amplifier control signal SAN.

When the sense amplifier driving signal providing circuit 405 is configured in the same form as the sense amplifier driving signal providing circuit 404 of FIG. 6, the sense amplifier driving signal providing circuit 405 may generate the first driving signal RTO1, the third driving signal RTO2, the fifth driving signal RTO3 and the seventh driving signal RTO4 by driving four power supply voltages using four drivers, respectively, according to the first sense amplifier control signal SAP. Further, the sense amplifier driving signal providing circuit 405 may generate the second driving signal SB1, the fourth driving signal SB2, the sixth driving signal SB3 and the eighth driving signal SB4 by driving four ground voltages using four drivers, respectively, according to the second sense amplifier control signal SAN.

The sense amplifier circuit 1000 may include a plurality of sense amplifiers 1000-1 to 1000-8. The circuit configuration of the plurality of sense amplifiers 1000-1 to 1000-8 may be the same as that in FIG. 4. Adjacent sense amplifiers among the plurality of sense amplifiers 1000-1 to 1000-8 may be configured to receive driving signals through nodes of different signal lines. The adjacent sense amplifiers may be determined based on the order of bit lines coupled to the adjacent sense amplifiers.

Among the plurality of sense amplifiers 1000-1 to 1000-8, a first sense amplifier group 1000-1 and 1000-5 coupled to a first bit line group BL0, BL8, BLB0 and BLB8 may be driven in response to the first driving signal set RTO1 and SB1 provided through the first signal line set 451 and 452. Among the plurality of sense amplifiers 1000-1 to 1000-8, a second sense amplifier group 1000-2 and 1000-6 coupled to a second bit line group BL2, BL10, BLB2 and BLB10 may be driven in response to the second driving signal set RTO2 and SB2 provided through the second signal line set 453 and 454. Among the plurality of sense amplifiers 1000-1 to 1000-8, a third sense amplifier group 1000-3 and 1000-7 coupled to a third bit line group BL4, BL12, BLB4 and BLB12 may be driven in response to the third driving signal set RTO3 and SB3 provided through the third signal line set 455 and 456. Among the plurality of sense amplifiers 1000-1 to 1000-8, a fourth sense amplifier group 1000-4 and 1000-8 coupled to a fourth bit line group BL6, BL14, BLB6 and BLB14 may be driven in response to the fourth driving signal set RTO4 and SB4 provided through the fourth signal line set 457 and 458.

A first sense amplifier 1000-1 may be provided with the first driving signal RTO1 through a node of the first signal line 451, and may be provided with the second driving signal SB1 through a node of the second signal line 452. The first sense amplifier 1000-1 may sense and amplify a voltage level difference between the driving bit line BL0 and the reference bit line BLB0 in response to the first driving signal RTO1 and the second driving signal SB1.

A second sense amplifier 1000-2 may be provided with the third driving signal RTO2 through a node of the third signal line 453, and may be provided with the fourth driving signal SB2 through a node of the fourth signal line 454. The second sense amplifier 1000-2 may sense and amplify a voltage level difference between the driving bit line BL2 and the reference bit line BLB2 in response to the third driving signal RTO2 and the fourth driving signal SB2.

A third sense amplifier 1000-3 may be provided with the fifth driving signal RTO3 through a node of the fifth signal line 455, and may be provided with the sixth driving signal SB3 through a node of the sixth signal line 456. The third sense amplifier 1000-3 may sense and amplify a voltage level difference between the driving bit line BL4 and the reference bit line BLB4 in response to the fifth driving signal RTO3 and the sixth driving signal SB3.

A fourth sense amplifier 1000-4 may be provided with the seventh driving signal RTO4 through a node of the seventh signal line 457, and may be provided with the eighth driving signal SB4 through a node of the eighth signal line 458. The fourth sense amplifier 1000-4 may sense and amplify a voltage level difference between the driving bit line BL6 and the reference bit line BLB6 in response to the seventh driving signal RTO4 and the eighth driving signal SB4.

The fifth sense amplifier 1000-5 may sense and amplify a voltage level difference between the driving bit line BL8 and the reference bit line BLB8 in response to the first driving signal RTO1 and the second driving signal SB1 provided through a node of the first signal line 451 and a node of the second signal line 452.

The sixth sense amplifier 1000-6 may sense and amplify a voltage level difference between the driving bit line BL10 and the reference bit line BLB10 in response to the third driving signal RTO2 and the fourth driving signal SB2 provided through a node of the third signal line 453 and a node of the fourth signal line 454.

The seventh sense amplifier 1000-7 may sense and amplify a voltage level difference between the driving bit line BL12 and the reference bit line BLB12 in response to the fifth driving signal RTO3 and the sixth driving signal SB3 provided through a node of the fifth signal line 455 and a node of the sixth signal line 456.

The eighth sense amplifier 1000-8 may sense and amplify a voltage level difference between the driving bit line BL14 and the reference bit line BLB14 in response to the seventh driving signal RTO4 and the eighth driving signal SB4 provided through a node of the seventh signal line 457 and a node of the eighth signal line 458.

As described above, in the embodiment, adjacent sense amplifiers, that is, the first to eighth sense amplifiers 1000-1 to 1000-8, may be provided with different driving signals through nodes of different signal lines, respectively. In particular, a preset unit group, for example, all of four sense amplifiers, may be provided with driving signals through nodes of different signal lines, respectively.

The numbers of memory cells, bit lines, word lines and sense amplifiers according to FIG. 7 described above are only according to an example of an embodiment and are not limited, and may vary according to memory capacity and a design method. In the above-described embodiment, a plurality of sense amplifiers are divided into a plurality of groups, for example, four groups, and the divided sense amplifier groups are activated according to the first driving signal set RTO1 and SB1, the second driving signal set RTO2 and SB2, the third driving signal set RTO3 and SB3 and the fourth driving signal set RTO4 and SB4, respectively, provided through respective signal lines, which makes it possible to reduce noise between adjacent bit lines.

While various embodiments have been described above, it will be understood to those skilled in the art that the embodiments described are examples only. Accordingly, the semiconductor apparatus described herein should not be limited based on the described embodiments.

What is claimed is:

1. A semiconductor apparatus comprising:
a plurality of bit lines;
a plurality of sense amplifiers coupled to the plurality of bit lines, respectively, and each sense amplifier is configured to, when activated, sense and amplify corresponding signals received from a driving bit line and a reference bit line from the plurality of bit lines coupled, respectively, to a sense amplifier from the plurality of sense amplifiers; and
a sense amplifier driving signal providing circuit configured to activate different groups of sense amplifiers, each of the groups of sense amplifiers including one or more adjacent sense amplifiers among the plurality of sense amplifiers, by respectively providing different driving signals through nodes of different signal lines to the groups of sense amplifiers.

2. The semiconductor apparatus according to claim 1, wherein the adjacent sense amplifiers are determined based on order of bit lines coupled to the adjacent sense amplifiers among the plurality of bit lines.

3. The semiconductor apparatus according to claim 1, wherein the sense amplifier driving signal providing circuit comprises:
a driver configured to output the different driving signals, generated by branching a signal generated in response to a sense amplifier control signal, to the different signal lines.

4. The semiconductor apparatus according to claim 1, wherein the sense amplifier driving signal providing circuit comprises:
a plurality of drivers configured to output the different driving signals, generated by using a first power source in response to a sense amplifier control signal, to the different signal lines.

5. The semiconductor apparatus according to claim 1, wherein the sense amplifier driving signal providing circuit comprises:
a plurality of drivers configured to output the different driving signals, generated by using a plurality of power sources in response to a sense amplifier control signal, to the different signal lines.

6. A semiconductor apparatus comprising:
a plurality of bit lines;
a plurality of sense amplifiers coupled to the plurality of bit lines, divided into a plurality of sense amplifier groups, and each configured to sense and amplify a voltage difference between two bit lines coupled to a sense amplifier; and
a sense amplifier driving signal providing circuit configured to provide a plurality of driving signal sets to the plurality of sense amplifier groups, respectively.

7. The semiconductor apparatus according to claim 6, wherein
the plurality of sense amplifier groups include a first sense amplifier group and a second sense amplifier group, and
the first sense amplifier group is coupled to even-ordered bit lines among the plurality of bit lines, and the second sense amplifier group is coupled to odd-ordered bit lines among the plurality of bit lines.

8. The semiconductor apparatus according to claim 6, wherein
the plurality of sense amplifier groups include a first sense amplifier group and a second sense amplifier group, and
the first sense amplifier group is configured to be provided with a first driving signal set through nodes of a first signal line set, and the second sense amplifier group is configured to be provided with a second driving signal set through nodes of a second signal line set.

9. The semiconductor apparatus according to claim 6, wherein the sense amplifier driving signal providing circuit comprises:
a driver configured to, by branching signals generated in response to a first sense amplifier control signal and a second sense amplifier control signal, output branched signals as a first driving signal set through a first signal line set, and output branched signals as a second driving signal set through a second signal line set.

10. The semiconductor apparatus according to claim 6, wherein the sense amplifier driving signal providing circuit comprises:
a first driver set configured to generate a first driving signal set by using a first power source set in response to a first sense amplifier control signal and a second sense amplifier control signal, and output the first driving signal set through a first signal line set; and
a second driver set configured to generate a second driving signal set by using the first power source set in response to the first sense amplifier control signal and the second sense amplifier control signal, and output the second driving signal set through a second signal line set.

11. The semiconductor apparatus according to claim 6, wherein the sense amplifier driving signal providing circuit comprises:
a first driver set configured to generate a first driving signal set by using a first power source set in response to a first sense amplifier control signal and a second sense amplifier control signal, and output the first driving signal set through a first signal line set; and
a second driver set configured to generate a second driving signal set by using a second power source set in response to the first sense amplifier control signal and the second sense amplifier control signal, and output the second driving signal set through a second signal line set.

12. A semiconductor apparatus comprising:
a first cell mat including a plurality of driving bit lines;
a second cell mat including a plurality of reference bit lines;
a plurality of sense amplifiers coupled to some of the plurality of driving bit lines and some of the plurality of reference bit lines, and each configured to sense and amplify a voltage difference between two bit lines coupled to a sense amplifier; and
a sense amplifier driving signal providing circuit configured to drive adjacent sense amplifiers among the plurality of sense amplifiers, by providing different driving signals through nodes of different signal lines to the adjacent signal lines.

13. The semiconductor apparatus according to claim 12, wherein the adjacent sense amplifiers are determined based on order of bit lines coupled to the adjacent sense amplifiers among the plurality of bit lines.

14. The semiconductor apparatus according to claim 12, wherein the sense amplifier driving signal providing circuit comprises:
a driver configured to output the different driving signals, generated by branching a signal generated in response to a sense amplifier control signal, to the different signal lines.

15. The semiconductor apparatus according to claim 12, wherein the sense amplifier driving signal providing circuit comprises:
a plurality of drivers configured to output the different driving signals, generated by using a first power source in response to a sense amplifier control signal, to the different signal lines.

16. The semiconductor apparatus according to claim 12, wherein the sense amplifier driving signal providing circuit comprises:
a plurality of drivers configured to output the different driving signals, generated by using a plurality of power sources in response to a sense amplifier control signal, to the different signal lines.

17. A semiconductor apparatus comprising:
a first cell mat including a plurality of driving bit lines;
a second cell mat including a plurality of reference bit lines;
a plurality of sense amplifiers coupled to some of the plurality of driving bit lines and some of the plurality of reference bit lines, divided into a plurality of sense amplifier groups, and each configured to sense and amplify a voltage difference between two bit lines coupled to a sense amplifier; and
a sense amplifier driving signal providing circuit configured to provide a plurality of driving signal sets to the plurality of sense amplifier groups, respectively.

18. The semiconductor apparatus according to claim 17, wherein
the plurality of sense amplifier groups include a first sense amplifier group and a second sense amplifier group, and
the first sense amplifier group is coupled to even-ordered bit lines among the plurality of bit lines, and the second sense amplifier group is coupled to odd-ordered bit lines among the plurality of bit lines.

19. The semiconductor apparatus according to claim 17, wherein
the plurality of sense amplifier groups include a first sense amplifier group and a second sense amplifier group, and
the first sense amplifier group is configured to be provided with a first driving signal set through nodes of a first signal line set, and the second sense amplifier group is configured to be provided with a second driving signal set through nodes of a second signal line set.

20. The semiconductor apparatus according to claim 17, wherein the sense amplifier driving signal providing circuit comprises:
a driver configured to, by branching signals generated in response to a first sense amplifier control signal and a second sense amplifier control signal, output branched signals as a first driving signal set through a first signal line set, and output branched signals as a second driving signal set through a second signal line set.

21. The semiconductor apparatus according to claim 17, wherein the sense amplifier driving signal providing circuit comprises:
a first driver set configured to generate a first driving signal set by using a first power source set in response to a first sense amplifier control signal and a second sense amplifier control signal, and output the first driving signal set through a first signal line set; and
a second driver set configured to generate a second driving signal set by using the first power source set in response to the first sense amplifier control signal and the second sense amplifier control signal, and output the second driving signal set through a second signal line set.

22. The semiconductor apparatus according to claim 17, wherein the sense amplifier driving signal providing circuit comprises:
a first driver set configured to generate a first driving signal set by using a first power source set in response to a first sense amplifier control signal and a second sense amplifier control signal, and output the first driving signal set through a first signal line set; and
a second driver set configured to generate a second driving signal set by using a second power source set in response to the first sense amplifier control signal and the second sense amplifier control signal, and output the second driving signal set through a second signal line set.
